(19) United States
(12) Patent Application Publication
(10) Pub. No.: US 2025/0259816 A1
(43) Pub. Date: Aug. 14, 2025

(54) ION STRIPPING APPARATUS AND ION IMPLANTATION SYSTEM WITH SELECTABLE STRIPPING GAS SOURCE

(71) Applicant: Axcelis Technologies, Inc., Beverly, MA (US)

(72) Inventors: Wilhelm Peter Platow, Newburyport, MA (US); Robert D. DuBois, Rolla, MO (US); Udo H. Verkerk, Toronto (CA); Neil J. Bassom, Hamilton, MA (US); Kevin W. Wenzel, Belmont, MA (US)

(21) Appl. No.: 19/049,103

(22) Filed: Feb. 10, 2025

Related U.S. Application Data
(60) Provisional application No. 63/552,232, filed on Feb. 12, 2024.

(51) Int. Cl. H01J 37/08; H01J 37/09; H01J 37/317

(52) U.S. Cl. CPC H01J 37/08; H01J 37/09; H01J 37/3171; H01J 2237/0041; H01J 2237/0473; H01J 2237/04735

(57) ABSTRACT

An ion implantation system has a first linear accelerator for accelerating ions of an ion beam to a first energy along a beam path. A second linear accelerator positioned downstream of the first linear accelerator along the beam path accelerates the ions to a second energy. A charge stripper is positioned between the first and second linear accelerators and is at ground potential. A gas source enclosure selectively encloses a plurality of stripper gas containers in an enclosure environment at ground potential. Each of the plurality of stripper gas containers contains a respective stripper gas. A flow control apparatus can have one or more valves, mass flow controllers, and conduits that selectively fluidly couples each of the plurality of stripper gas containers to the charge stripper and that selectively controls a flow of each respective stripper gas to the charge stripper.

### REFERENCE TO RELATED APPLICATIONS

This application claims the benefit of U.S. Provisional Application Ser. No. 63/552,232 filed Feb. 12, 2024, entitled, “ION STRIPPING APPARATUS AND ION IMPLANTATION SYSTEM WITH SELECTABLE STRIPPING GAS SOURCE”, the contents of which are herein incorporated by reference in their entirety.

### TECHNICAL FIELD

The present invention relates generally to ion implantation systems, and more specifically to a stripper gas enclosure and a stripper apparatus configured to strip electrons from ions via a selection from plurality of stripper gases.

### BACKGROUND

In the manufacture of semiconductor devices, ion implantation is used to dope semiconductors with impurities. Ion implantation systems are often utilized to dope a workpiece, such as a semiconductor wafer, with ions from an ion beam, in order to either produce n- or p-type material doping, or to form passivation layers during fabrication of an integrated circuit. Such beam treatment is often used to selectively implant the wafers with impurities of a specified dopant material, at a predetermined energy level, and in controlled concentration, to produce a semiconductor material during fabrication of an integrated circuit. When used for doping semiconductor wafers, the ion implantation system injects a selected ion species into the workpiece to produce the desired extrinsic material. Implanting ions generated from source materials such as antimony, arsenic, or phosphorus, for example, results in an “n-type” extrinsic material wafer, whereas a “p-type” extrinsic material wafer often results from ions generated with source materials such as boron, gallium, or indium.

A typical ion implanter includes an ion source, an ion extraction device, a mass analysis device, a beam transport device and a wafer processing device. The ion source generates ions of desired atomic or molecular dopant species. These ions are extracted from the source by an extraction system, typically a set of electrodes, which energize and direct the flow of ions from the source, forming an ion beam. Desired ions are separated from the ion beam in a mass analysis device, typically a magnetic dipole performing mass dispersion or separation of the extracted ion beam. The beam transport device, typically a vacuum system containing a series of focusing devices, transports the ion beam to the wafer processing device while maintaining desired properties of the ion beam. Finally, semiconductor wafers are transferred in to and out of the wafer processing device via a wafer handling system, which may include one or more robotic arms, for placing a wafer to be treated in front of the ion beam and removing treated wafers from the ion implanter.

### SUMMARY

The following presents a simplified summary of the disclosure in order to provide a basic understanding of some aspects of the disclosure. This summary is not an extensive overview of the disclosure. It is intended to neither identify key or critical elements of the invention nor delineate the scope of the invention. Its purpose is to present some concepts of the disclosure in a simplified form as a prelude to the more detailed description that is presented later.

Aspects of the disclosure facilitate ion implantation processes for implanting ions into a workpiece. According to one exemplary aspect, an ion implantation system is provided having an ion source configured to form an ion beam, a beamline assembly configured to selectively transport the ion beam, and an end station is configured to accept the ion beam for implantation of the aluminum ions into a workpiece.

In accordance with one exemplary aspect, an ion implantation system is provided having a first linear accelerator configured to accelerate ions of an ion beam to a first energy along a beam path. A second linear accelerator is positioned downstream of the first linear accelerator along the beam path, wherein the second linear accelerator is configured to accelerate the ions of the ion beam to a second energy. Further, a charge stripper is positioned between the first linear accelerator and the second linear accelerator along the beam path, wherein the charge stripper is at ground potential. A gas source enclosure is further provided and configured to selectively enclose a plurality of stripper gas containers in an enclosure environment, wherein the enclosure environment is at ground potential, and wherein each of the plurality of stripper gas containers has a respective stripper gas associated therewith. A flow control apparatus is further provided and configured to selectively fluidly couple each of the stripper gas containers to the charge stripper and to selectively control a flow of each respective stripper gas to the charge stripper.

In one example, the flow control apparatus comprises a mass flow controller. The mass flow controller, for example, is configured to control a respective flow of each respective stripper gas to the charge stripper. In another example, the flow control apparatus can comprise at least one valve selectively fluidly coupled to each of the plurality of stripper gas containers. The at least one valve, for example, is configured provide selective fluid communication between the plurality of stripper gas containers and the at least one mass flow controller. In one example, a plurality of valves are respectively selectively coupled to each of the plurality of stripper gas containers. Further, a plurality of mass flow controllers can be respectively fluidly coupled to the plurality of valves, wherein each of the plurality of mass flow controllers is further configured to control a respective flow of each respective stripper gas to the charge stripper.

In another example, one or more conduits are fluidly coupled to the charge stripper. For example, the charge stripper can comprise a stripper tube, wherein the one or more conduits are fluidly coupled to the stripper tube, and wherein the flow control apparatus is further configured to selectively fluidly couple each of the stripper gas containers to the stripper tube via the plurality of valves and the one or more conduits. A common conduit, for example, can fluidly couple the one or more conduits to the stripper tube, wherein the flow control apparatus is configured to concurrently fluidly couple two or more of the stripper gas containers to the stripper tube via the one or more conduits and the common conduit, thus providing a mixing of the respective stripper gases in the conduit before entering the stripper tube.

The plurality of stripper gases can comprise a respective gas species used in the formation of the ion beam, whereby the plurality of stripper gases can be unique for each of the plurality of stripper gas containers.

In another example, the first linear accelerator and the second linear accelerator are configured to produce x-ray radiation concurrent with the respective acceleration of the ions of the ion beam to the respective first energy and the second energy, whereby a radiation shield is provided and configured to prevent the x-ray radiation from reaching the enclosure environment.

In accordance with another exemplary aspect of the disclosure, a stripper apparatus for an ion implantation system is provided. The stripper apparatus, for example, comprises a charge stripper positioned between a first accelerator and a second accelerator along a beam path of an ion beam, wherein the charge stripper is at ground potential. The first and second accelerators, for example, can comprise respective RF linear accelerators. The stripper apparatus can comprise a gas source enclosure configured to selectively enclose a plurality of stripper gas containers in an enclosure environment. The enclosure environment, for example, is at ground potential. Further, each of the plurality of stripper gas containers has a respective stripper gas associated therewith. Further, the stripper apparatus can comprise a flow control apparatus configured to selectively fluidly couple each of the stripper gas containers to the charge stripper and to selectively control a flow of each respective stripper gas to the charge stripper.

The stripper apparatus can further comprise one or more conduits fluidly coupled to a stripper tube of the charge stripper, wherein the flow control apparatus is further configured to selectively fluidly couple each of the stripper gas containers to the stripper tube via the plurality of valves and the one or more conduits. A common conduit can be fluidly coupled to the stripper tube and the one or more conduits, wherein the flow control apparatus is configured to concurrently fluidly couple two or more of the stripper gas containers to the stripper tube via the one or more conduits and the common conduit.

According to still another exemplary aspect, a charge stripping system for an ion implantation system is provided, comprising a charge stripper positioned between a first RF linear accelerator and a second RF linear accelerator along a beam path of an ion beam, wherein the charge stripper comprises a stripper tube and is at ground potential. The charge stripping system further comprises a gas source enclosure is configured to selectively enclose a plurality of stripper gas containers in an enclosure environment, wherein the enclosure environment is at ground potential, and wherein each of the plurality of stripper gas containers has a respective stripper gas associated therewith. Further, the charge stripping system comprises a plurality of conduits fluidly coupling the stripper tube to the plurality of stripper gas containers, whereby a flow control apparatus is configured to selectively control a flow of each respective stripper gas through the plurality of conduits to the stripper tube.

The above summary is merely intended to give a brief overview of some features of some embodiments of the present disclosure, and other embodiments may comprise additional and/or different features than the ones mentioned above. In particular, this summary is not to be construed to be limiting the scope of the present application. Thus, to the accomplishment of the foregoing and related ends, the disclosure comprises the features hereinafter described and particularly pointed out in the claims. The following description and the annexed drawings set forth in detail certain illustrative embodiments of the disclosure. These embodiments are indicative, however, of a few of the various ways in which the principles of the disclosure may be employed. Other objects, advantages and novel features of the disclosure will become apparent from the following detailed description of the disclosure when considered in conjunction with the drawings.

### BRIEF DESCRIPTION OF THE DRAWINGS

FIG. 1 is a schematic block diagram of an ion implantation system having a selectable gas source for a stripper apparatus in accordance with several example aspects of the present disclosure.

FIG. 2 is a schematic block diagram of another ion implantation system having a selectable gas source for a stripper apparatus in accordance with several example aspects of the present disclosure.

FIG. 3 illustrates a perspective view of an exemplary charge stripper comprising in accordance with another aspect of the present disclosure.

FIG. 4 illustrates a cross-sectional view of the charge stripper of FIG. 3 in accordance with another aspect of the present disclosure.

FIG. 5 is a chart illustrating efficiencies of various stripper gases for an example arsenic ion beam.

FIG. 6 is a chart illustrating efficiencies of various stripper gases for an example boron ion beam.

### DETAILED DESCRIPTION

The present disclosure is directed generally toward an ion implantation system and a source for a charge stripper gas associated therewith. More particularly, the present disclosure is directed toward an enclosure for maintaining stripper gas containers for a charge stripper for said ion implantation system. The present disclosure positions a plurality of stripper gas containers in a gas enclosure associated with an ion source, whereby the gas enclosure is maintained at a ground potential. Accordingly, containment and safety aspects of the gas enclosure advantageously ameliorate duplicative hardware and gas delivery piping.

Accordingly, the present invention will now be described with reference to the drawings, wherein like reference numerals may be used to refer to like elements throughout. It is to be understood that the description of these aspects are merely illustrative and that they should not be interpreted in a limiting sense. In the following description, for purposes of explanation, numerous specific details are set forth in order to provide a thorough understanding of the present invention. It will be evident to one skilled in the art, however, that the present invention may be practiced without these specific details. Further, the scope of the invention is not intended to be limited by the embodiments or examples described hereinafter with reference to the accompanying drawings, but is intended to be only limited by the appended claims and equivalents thereof.

It is also noted that the drawings are provided to give an illustration of some aspects of embodiments of the present disclosure and therefore are to be regarded as schematic only. In particular, the elements shown in the drawings are not necessarily to scale with each other, and the placement of various elements in the drawings is chosen to provide a clear understanding of the respective embodiment and is not to be construed as necessarily being a representation of the actual relative locations of the various components in implementations according to an embodiment of the invention. Furthermore, the features of the various embodiments and examples described herein may be combined with each other unless specifically noted otherwise.

It is also to be understood that in the following description, any direct connection or coupling between functional blocks, devices, components, circuit elements or other physical or functional units shown in the drawings or described herein could also be implemented by an indirect connection or coupling. Furthermore, it is to be appreciated that functional blocks or units shown in the drawings may be implemented as separate features or circuits in one embodiment, and may also or alternatively be fully or partially implemented in a common feature or circuit in another embodiment. For example, several functional blocks may be implemented as software running on a common processor, such as a signal processor. It is further to be understood that any connection which is described as being wire-based in the following specification may also be implemented as a wireless communication, unless noted to the contrary.

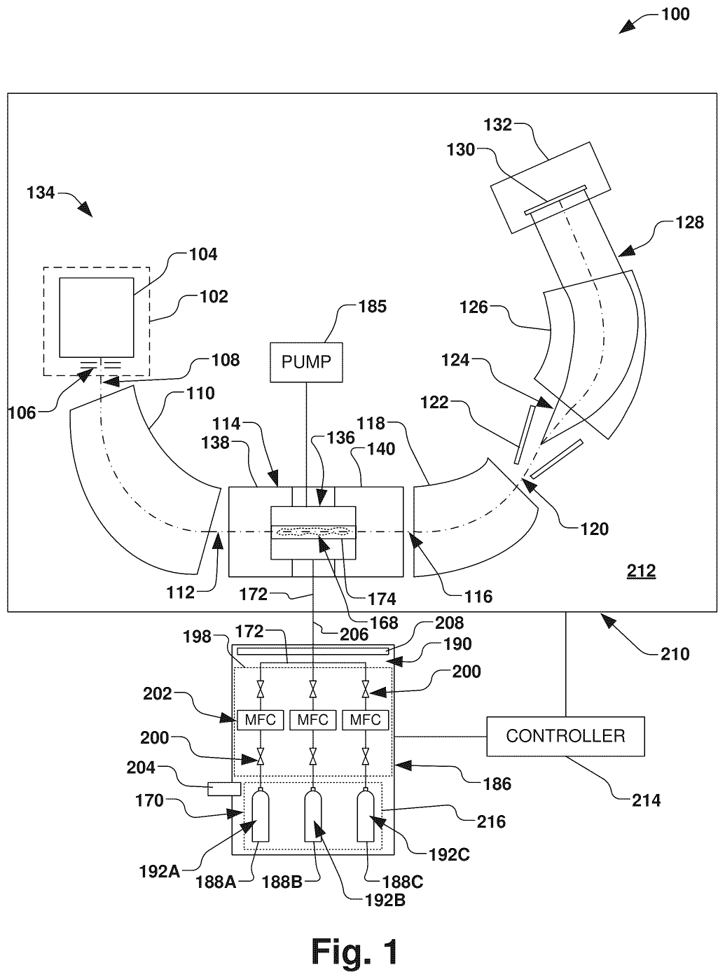

Referring now to the figures, in order to gain a better understanding of the present disclosure, FIG. 1 illustrates an ion implantation system 100 in accordance with various exemplified aspects of the present disclosure. The ion implantation system 100, for example, can sometimes be referred to as a post acceleration implanter, as will be discussed infra. The ion implantation system 100 of FIG. 1, for example, comprises an ion source 102, which comprises an ion source chamber 104 and an extraction electrode 106 to extract and accelerate ions to an intermediate energy, generally forming an ion beam 108. The ion beam 108 extracted from the ion source chamber 104, for example, can comprise any beam species, such as arsenic, boron, phosphorus, or other species.

A mass analyzer 110, for example, removes unwanted ion mass and charge species from the ion beam 108 to define a mass analyzed ion beam 112, whereby an accelerator 114 is configured to accelerate the analyzed ion beam to a define an accelerated ion beam 116. In accordance with one example of the present disclosure, the accelerator 114, for example, comprises an RF linear particle accelerator (LINAC) in which ions are accelerated repeatedly by an RF field.

The ion implantation system 100, for example, further comprises an energy filter 118 positioned downstream of the accelerator 114, whereby the energy filter is configured to remove unwanted energy spectrum from the accelerated ion beam 116 emerging from the output of accelerator 114, thereby defining a final energy ion beam 120. A beam scanner 122, for example, is configured to scan the final energy ion beam 120 exiting from the energy filter 118, whereby the final energy ion beam is scanned back and forth at a fast frequency to define a scanned ion beam 124. The beam scanner 122, for example, is configured to electrostatically or electromagnetically scan the final energy ion beam 120 to define the scanned ion beam 124.

The scanned ion beam 124 is further passed into an angle corrector lens 126, wherein the angle corrector lens is configured to convert the fanning-out scanned beam 124 to a final ion beam 128. The angle corrector lens 126, for example, can be configured to parallelize and shift the scanned ion beam 124 to define the final ion beam 128. The angle corrector lens 126, for example, can comprise electromagnetic or electrostatic devices configured to define the final ion beam 128.

The final ion beam 128, for example, is subsequently implanted into a workpiece 130 (e.g., a semiconductor wafer) that can be selectively positioned in a process chamber or end station 132. The workpiece 130, for example, can be moved orthogonal to the final ion beam 128 (e.g., moving in and out of the paper) in a hybrid scan scheme to irradiate the entire surface of the workpiece 130 uniformly. It is noted that the present disclosure appreciates various other mechanisms and methods for scanning the final ion beam 128 with respect to the workpiece 130, and all such mechanisms and methods are contemplated as falling within the scope of the present disclosure.

The ion implantation system 100, for example, can be configured as a hybrid parallel-scan single-workpiece ion implantation system. The implantation system 100 for example, can also referred to as a post-acceleration implanter 134, since the accelerator 114 is positioned downstream of the mass analyzer 110 and upstream of the energy filter 118. Ion implanters of this type, for example, provide the energy filter 118 after the accelerator 114 in order to remove unwanted energy spectrum in the output of accelerator. It should be noted, however, that the present disclosure appreciates that various aspects of the present disclosure may be implemented in association with any type of ion implantation system, including, but not limited to the exemplary system 100 of FIG. 1.

In one example, the final kinetic energy of ion particles passing through the accelerator 114 can be increased by increasing the charge state of the ions. While ion beams having higher charge states can be extracted directly from the ion source 102, such higher state ion beams typically have significantly lower beam currents (e.g., by a factor of 5-10 when increasing the charge state by one). The present disclosure appreciates that it can be more advantageous to achieve higher beam currents by pre-accelerating the mass analyzed ion beam 112 having lower charge state ions extracted from the ion source 102, and subsequently guiding them through a target gas where electrons are stripped from the ions, thus increasing the charge state of the ions. Then, the ions of the higher charge state can be post-accelerated to a final energy. Typically, higher beam currents can be achieved in this manner as the stripping efficiency increases with an increase in the energy of the ions. The stripping efficiency, for example, can vary based on ion species such as boron (B), phosphorus (P), and arsenic (As), as well varying based on the desired charge state and selection of the target gas.

Thus, in accordance with the present disclosure, a charge stripper 136 is provided to increase the charge state of the mass analyzed ion beam 112 that enters the accelerator 114. The charge stripper 136 is particularly advantageous for achieving high energy ion beams, as the energy (E) of the ions is provided by:

$$E = qV , \qquad ( 1 )$$

where V is the acceleration voltage q is the charge state of the ions. Thus, in accordance with the present disclosure, the accelerator 114 comprises an RF linear accelerator having a number of accelerator stages (e.g., six or more) and resonators for generating an accelerating field, whereby the ion charge state can be increased in one embodiment by providing the charge stripper 136 within the accelerator 114 as shown in FIG. 1. As such, the ion particles are accelerated to a first energy before entering the charge stripper 136 via a first plurality of acceleration stages 138 within the accelerator 114. The ion particles are further accelerated to a second energy after exiting the charge stripper 136, for example, via a second plurality of acceleration stages 140 within the accelerator 114. For example, at least one of the plurality of accelerator stages can comprise the charge stripper 136 replacing the resonator(s) at that accelerator stage.

The first and second plurality of acceleration stages 138, 140 of the accelerator 114 can be either internal or external to the accelerator, and all such configurations are contemplated as falling within the scope of the present disclosure. For example, the accelerator 114 can take many forms and can comprise any number of accelerator stages defined by or within a single accelerator apparatus, such as illustrated in the example shown in FIG. 1. In another example, while not shown, the first plurality of acceleration stages of the accelerator 114 can be associated with the mass analyzer 110, whereby the ion beam 108 is both accelerated and mass analyzed before entering the charge stripper 136. In another example, the accelerator 114 can comprise a DC accelerator column (not shown). However, in such a configuration, components upstream of the DC accelerator column would be at high voltage potential.

It is noted that the energy filter 118 shown in the example of FIG. 1 can filter out some unwanted charge states. However, since the energy filter 118 is not immediately after the charge stripper 136 in the present example, the second plurality of acceleration stages 140 will accelerate the entire charge state distribution, thus potentially impeding a selection of the desired charge state, as the accelerated ion beam 116 may be contaminated with a charge state that has a different energy, but the same magnetic rigidity, as the desired charge state

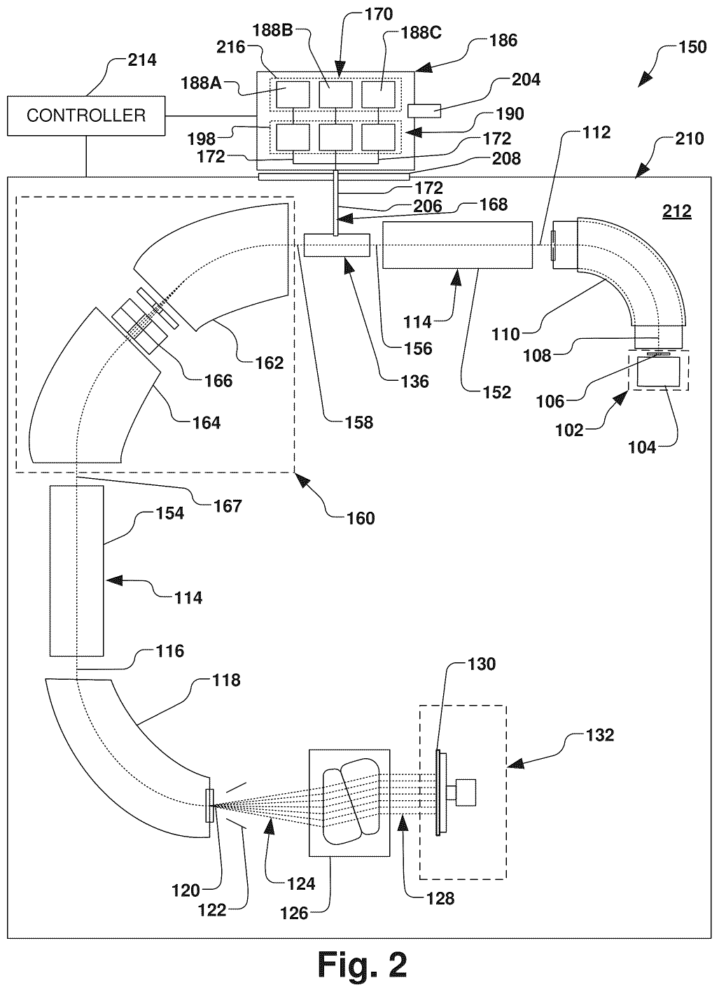

In another example, FIG. 2 illustrates an ion implantation system 150 having similar components to the ion implantation system 100 of FIG. 1. However, in the ion implantation system 150 of FIG. 2, the accelerator 114 is generally defined by a pre-accelerator 152 and a post-accelerator 154, whereby the charge stripper 136 is positioned between the pre-accelerator section and post-accelerator section. The pre-accelerator 152, for example, is an RF linear accelerator configured to pre-accelerate ions of the mass analyzed ion beam 112 that have been extracted from the ion source 102 at a lower charge state, thus defining a pre-accelerated ion beam 156.

The charge stripper 136 thus increases the charge state of the pre-accelerated ion beam 156 as discussed above to define a higher charge state ion beam 158. A charge selector 160, for example, is further positioned downstream of the pre-accelerator 152 and charge stripper 136, whereby the charge selector is configured to select desired ions of the higher charge state after the stripping process performed in the pre-accelerator 152. The charge selector 160, for example, comprises first and second dipole magnets 162, 164 having a quadrupole magnet 166 disposed therebetween, whereby the charge selector selectively passes only selected ions of the higher charge state ion beam 158 to define a selected charge state ion beam 167. The selected charge state ion beam 167 thus enters the post-accelerator 154 in order to attain a maximum energy that is higher than the original-charge state ions and to define the accelerated ion beam 116.

In comparing the configurations of the ion implantation systems 100, 150 of respective FIGS. 1 and 2, the charge selector 160 shown in FIG. 2, for example, can be configured to select only a specific ion charge state of the desired ion species, while preventing other charge state ions from entering the post-accelerator 154. Thus, in some circumstances, the configuration of the ion implantation system 150 shown in FIG. 2 can provide a significantly purer energy spectrum of the desired ions after acceleration and charge selection by the provision of the pre-accelerator 152, post-accelerator 154, charge stripper 136, and charge selector 160, as compared to the configuration of the ion implantation system 100 illustrated in FIG. 1. Further, the ion implantation system 150 substantially avoids possible charge and energy contamination, as the probability of attaining beams having similar magnetic rigidity, but with different charge states and energies, is reduced to approximately zero.

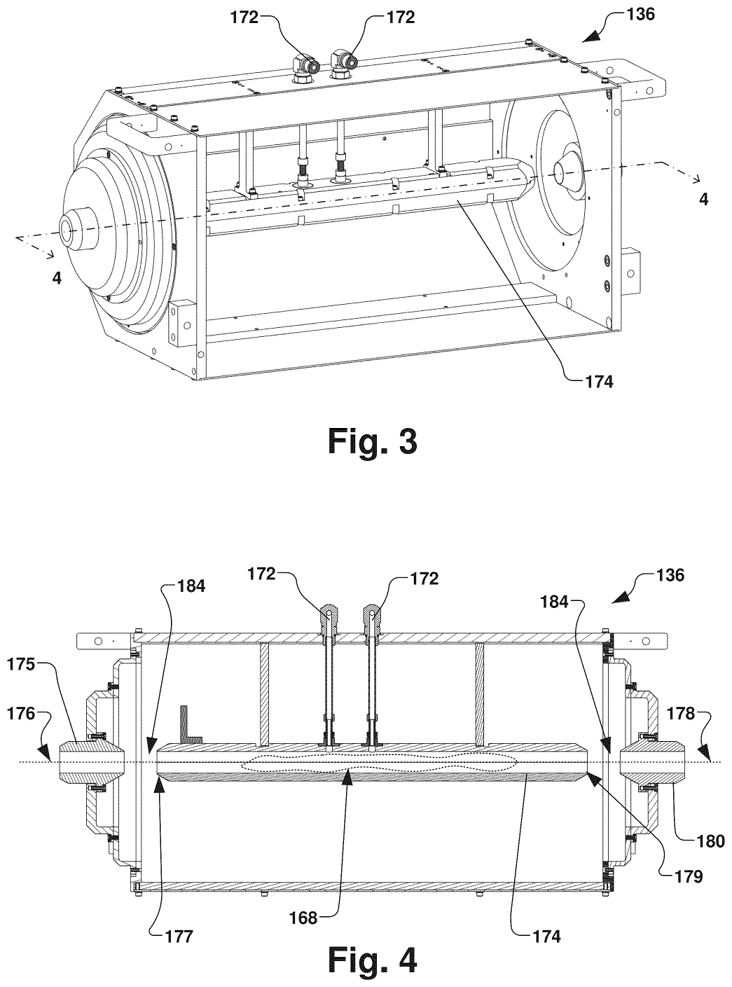

In accordance with various aspects of the disclosure, the charge stripper 136 of either of FIGS. 1 and 2, for example, is filled with a stripper gas 168 supplied from a gas source 170 via one or more conduits 172, whereby the gas is selected to strip electrons from the ions passing through the stripper. FIGS. 3-4 illustrate an example of the charge stripper 136, whereby the charge stripper 136 comprises a stripper tube 174, into which the stripper gas 168 of FIGS. 1-2 is selectively flowed. As illustrated in FIG. 4, the charge stripper 136, for example, comprises charge stripper inlet 175 through which an inbound ion beam 176 enters the charge stripper. The inbound ion beam 176, for example, can comprise one of the mass analyzed ion beam 112 of FIG. 1 or the pre-accelerated ion beam 156 of FIG. 2, or any ion beam at any stage of acceleration of FIGS. 1-2. After entering the charge stripper 136 of FIG. 4, for example, the inbound ion beam 176 passes into the stripper tube 174 through a stripper tube entrance 177, whereby the stripper gas 168 is flowed through the one or more conduits 172 into the stripper tube. As the inbound ion beam 176 passes through the stripper gas 168, electrons are stripped from the constituent ions, whereby an outbound ion beam 178 (e.g., the higher charge state ion beam 158 of FIG. 2) emerges from the stripper tube 174 through a stripper tube exit 179. The outbound ion beam 178 of FIG. 4, for example, subsequently exits the charge stripper 136 through a charge stripper outlet 180. The outbound ion beam 178, for example, can have a charge state distribution associated therewith, whereby a desired charge state can be further selected by the charge selector 160 of FIG. 2 and define the selected charge state ion beam 167.

In accordance with one example, one or more gaps 184 upstream and downstream of the stripper tube 174 of FIG. 4 are differentially pumped to lower the pressure in the gaps and remove the stripper gas 168 therefrom, such that acceleration stages upstream and downstream of the charge stripper 136 are not negatively affected by the stripper gas. For example, the one or more gaps 184 can be located between the charge stripper inlet 175 and stripper tube entrance 177, and between the charge stripper outlet 180 and the stripper tube exit 179. Such differential pumping can be provided in a plurality of stages, such as by providing two or more gaps 184 upstream and downstream of the stripper tube 174. In one example, one or more differential pumps 185 illustrated in FIG. 1 (e.g., a differential turbo pump) can be fluidly coupled to the charge stripper 136 to reduce or otherwise control a flow of the stripper gas 168 into adjacent sections associated with the accelerator 114 of FIGS. 1-2 by differentially pumping the two or more gaps 184. For example, the one or more differential pumps 185 of FIG. 1 are fluidly coupled to the two or more gaps 184 between the stripper tube 174, the charge stripper inlet 175, and the charge stripper outlet 180 illustrated in FIG. 4, wherein the one or more differential pumps are configured to differentially pump the two or more gaps to control a flow of the stripper gas 168 from the charge stripper 136.

Further in accordance with the present disclosure, the charge stripper 136 is provided at ground potential. The charge stripper 136, for example, is thus particularly applicable to an RF linear accelerator-based ion implantation system, such as the so-called XEmax High Energy Implanter manufactured by Axcelis Technologies of Beverly, MA.

The present disclosure appreciates that electron stripping efficiency associated with stripper gas 168 can vary widely based on the species of the stripper gas. Thus, in accordance with one example aspect of the disclosure, a gas source enclosure 186 is further provided in the ion implantation system 100, 150, as illustrated in FIGS. 1-2, wherein the gas source enclosure is further provided at ground potential. The gas source enclosure 186, for example, can be defined within a boundary of the respective ion implantation system 100, 150, attached or otherwise coupled to the respective system, or separate from the system, based on a desired footprint and ease of access and maintenance, thereof. The gas source enclosure 186, for example, is configured to permit an operator of the respective ion implantation system 100, 150 to select between various species of the stripper gas depending on implant species, charge state and energy, thus maximizing beam current and throughput.

The gas source enclosure 186, for example, is configured to selectively enclose a plurality of stripper gas containers 188 (illustrated in the example as stripper containers 188A-188C) in an enclosure environment 190, wherein the enclosure environment is at ground potential. It is noted that while only three stripper gas containers 188 are illustrated, any number of stripper gas containers and respective gas species are contemplated. Each of the plurality of stripper gas containers 188A-188C, for example, is configured to provide a respective gas species 192 (illustrated as gas species 192A-192C) of the stripper gas 168 to the charge stripper 136. It is noted that while only three stripper gas containers 188 are illustrated, any number of stripper gas containers and respective gas species 192 are contemplated. The gas species 192A-192C contained within each of the plurality of stripper containers 188A-188C, for example, is determined based on the implant species, charge state, and energy of the desired implant, whereby optimal electron stripping efficiency is achieved for the desired implant.

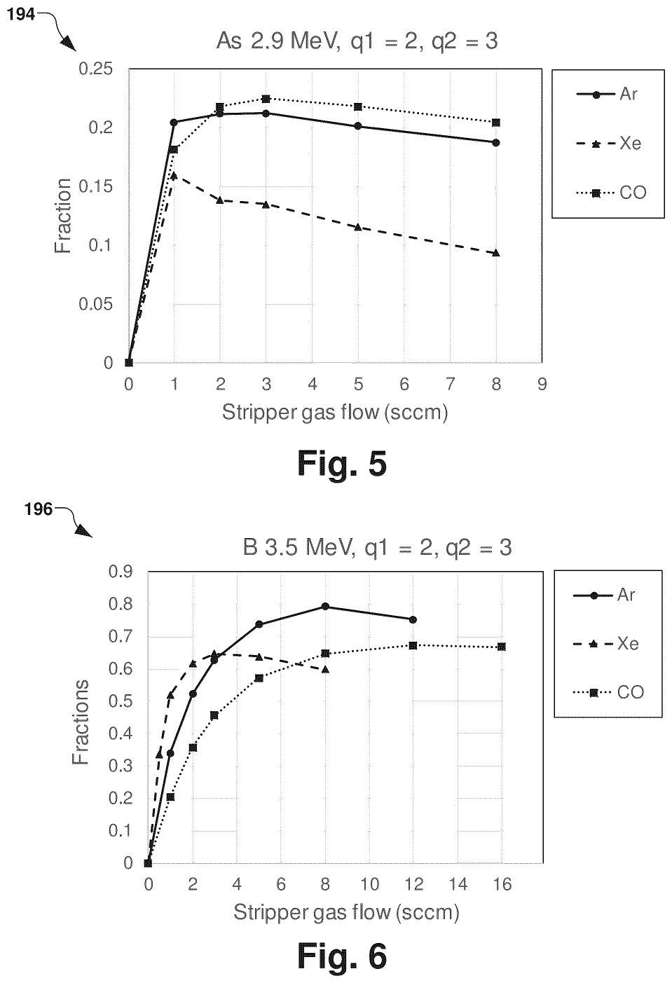

For example, the desired implant species can be arsenic ions, whereby the arsenic ions are pre-accelerated to As2+ via the first plurality of acceleration stages 138 of FIG. 1 or the pre-accelerator 152 of FIG. 2. The charge stripper 136, for example, can be configured to strip electrons from the As2+ ions to define As3+ that are post-accelerated by the respective second plurality of acceleration stages 140 of FIG. 1 or the post-accelerator 154 of FIG. 2. FIG. 5, for example, illustrates a chart 194 showing the highest beam current can be achieved with using carbon monoxide CO gas in the charge stripper 136 of FIGS. 1-2 for a 2.9 MeV arsenic ion beam. Similarly, the desired implant species for the same respective ion implantation system 100, 150 can be boron ions, whereby the boron ions are pre-accelerated to B2+ via the first plurality of acceleration stages 138 of FIG. 1 or the pre-accelerator 152 of FIG. 2, and the charge stripper 136 can be configured to strip electrons from the B2+ ions to define B3+ that are post-accelerated by the respective second plurality of acceleration stages 140 of FIG. 1 or the post-accelerator 154 of FIG. 2. As such, FIG. 6 illustrates a chart 196 showing that argon gas achieves the highest stripping efficiency, and therefore beam current. Other implant species, charge states, and energies of other desired implants can have similar charts associated therewith. The present disclosure notes that unexpected results were experimentally achieved showing a strong effect of stripping efficiency on target gas and beam species, in combination with beam energy.

Accordingly, each of the plurality of stripper gas containers 188A-188C, for example, is configured to selectively provide a respective stripper gas species 192A-192C of the stripper gas 168 to the charge stripper 136 based on input provided by an operator of the respective ion implantation system 100, 150 of FIGS. 1-2. Furthermore, a flow control apparatus 198 is provided and configured to selectively fluidly couple each of the stripper gas containers 188A-188C to the charge stripper 136 via the one or more conduits 172. The flow control apparatus 198, for example, can comprise one or more valves 200 and one or more mass flow controllers (MFC) 202 illustrated in FIG. 1 that are configured to selectively control a flow of each respective stripper gas species 192A-192C of the stripper gas 168 to the charge stripper 136. Each respective stripper gas species 192A-192C, for example, can be unique for each of the plurality of stripper gas containers 188A-188C, or multiple stripper gas containers can contain the same stripper gas species. Further, an exhaust vent 204 is provided to provide a venting of the enclosure environment 190 to atmosphere or external region in case of a leak associated with the stripper gas containers 188A-188C, which can be especially advantageous for poisonous or explosive gas species.

In accordance with one example, the flow control apparatus 198 comprises at least one mass flow controller 202 configured to jointly control a respective flow of each respective stripper gas species 192A-192C of the stripper gas 168 to the charge stripper 136. The flow control apparatus 198, for example, can further comprise at least one valve 200 selectively fluidly coupled to each of the plurality of stripper gas containers 188A-188C, wherein the at least one valve is configured provide selective fluid communication between the plurality of stripper gas containers and the at least one mass flow controller 202.

In another example, a plurality of mass flow controllers 202 are respectively fluidly coupled to the plurality of valves 200, wherein each of the plurality of mass flow controllers is further configured to control a respective flow of each of each respective stripper gas species 192A-192C of the desired stripper gas 168 to the charge stripper 136. Additionally, the present disclosure appreciates that co-flowing two or more of the stripper gas species 192 can allow for advantageous mixing of the two or more stripper gas species in the stripper tube 174, which can further increase stripping efficiency. For example, a common conduit 206 is fluidly coupled to the stripper tube 174, whereby the one or more conduits 172 are further fluidly coupled to the common conduit. Thus, the flow control apparatus 198 can be configured to selectively flow each respective stripper gas species 192A-192C through the one or more conduits 172 and the common conduit 206. For example, the flow control apparatus 198 can control the plurality of valves 200 such that any number of the stripper gas species 192A-192C can be individually or concurrently flowed through the one or more conduits and the common conduit 206 to the stripper tube 174. For example, concurrent flowing of several stripper gas species 192 through the common conduit can advantageously allow or promote mixing of the several stripper gas species prior to entering into the stripper tube 174, whereby stripping efficiency can be further increased.

In accordance with another example aspect of the disclosure, one or more of the first and second plurality of acceleration stages 138, 140 of FIG. 1 and the pre-accelerator 152 and post-accelerator 154 of FIG. 2 can produce x-ray radiation concurrent with the acceleration of the ions of the ion beam to the respective first energy and the second energy. As such, one or more radiation shields 208 can be further provided in association with the gas source enclosure 186, whereby the one or more radiation shields 208 are configured to prevent the x-ray radiation from reaching the enclosure environment 190 (e.g., an atmospheric environment). The one or more radiation shields 208, for example, can comprise a system enclosure 210.

As illustrated in FIG. 1, the system enclosure 210 encloses at least the first and second plurality of acceleration stages 138, 140 and the charge stripper 136 in an operating environment 212, and wherein the enclosure environment 190 is isolated from the operating environment by at least the one or more radiation shields. As illustrated in FIG. 2, the system enclosure 210 encloses at least the pre-accelerator 152 and post-accelerator 154 and the charge stripper 136 in the operating environment 212, wherein the enclosure environment 190 is isolated from the operating environment by at least the one or more radiation shields.

In accordance with yet another example, a controller 214 is provided for selective control of one or more components of the respective ion implantation system 100, 150 of FIGS. 1-2. The controller 214, for example, can be configured to control a flow rate of the stripper gas 168 from the respective stripper gas source 188A-188C into the charge stripper 136. The flow rate of the stripper gas 168 can be a function based on at least one of energy, current, and/or species and charge state of the inbound ion beam 176 of FIG. 4.

The present disclosure contemplates the gas source enclosure 186 comprising a gas box 216 providing a housing for the plurality of gas sources 188A-188C, whereby the gas box is the same potential (e.g., ground potential) as the charge stripper 136.

The plurality of gas sources 188A-188C, for example, can be plumbed into the stripper tube 174 via the one or more conduits 172 comprising conductive tubing (e.g., a stainless steel tube).

It is noted that the present disclosure is particularly advantageous in linear acceleration ion implantation systems, as opposed to conventional tandem accelerator ion implantation systems. While tandem accelerator ion implantation systems (also called tandem implanters) utilize gas stripping between two acceleration stages, the two acceleration stages are isolated via a high pressure tank that is filled with sulfur hexafluoride (SF₆). The configuration of such a configuration of the tandem accelerator provides the gas stripper at a high electrical potential. Further, due to the configuration of the tandem accelerator, space is very limited in the region of the gas stripper assembly, thus typically permitting only a single stripper gas bottle and a relatively small turbo pump for evacuating the region.

In the tandem implanter example, in order to change the stripper gas target, the entire high pressure tank would have to be drained of SF₆, the vacuum vessel (e.g., inside the accelerator column and stripper assembly) would be vented, and only then opened up for the stripper gas bottle be exchanged. Then, the high pressure tank would have to be refilled with SF₆, the vacuum would need to be reestablished, and the accelerator columns conditioned. Such a process in a tandem accelerator typically takes many hours, thus impacting productivity of the system.

Although the invention has been shown and described with respect to a certain embodiment or embodiments, it should be noted that the above-described embodiments serve only as examples for implementations of some embodiments of the present invention, and the application of the present invention is not restricted to these embodiments. In particular regard to the various functions performed by the above described components (assemblies, devices, circuits, etc.), the terms (including a reference to a “means”) used to describe such components are intended to correspond, unless otherwise indicated, to any component which performs the specified function of the described component (i.e., that is functionally equivalent), even though not structurally equivalent to the disclosed structure which performs the function in the herein illustrated exemplary embodiments of the invention. In addition, while a particular feature of the invention may have been disclosed with respect to only one of several embodiments, such feature may be combined with one or more other features of the other embodiments as may be desired and advantageous for any given or particular application. Accordingly, the present invention is not to be limited to the above-described embodiments, but is intended to be limited only by the appended claims and equivalents thereof.

1. An ion implantation system comprising:
a first linear accelerator configured to accelerate ions of an ion beam to a first energy along a beam path;
a second linear accelerator positioned downstream of the first linear accelerator along the beam path and configured to accelerate the ions of the ion beam to a second energy;
a charge stripper positioned between the first linear accelerator and the second linear accelerator along the beam path, wherein the charge stripper is at ground potential;
a gas source enclosure configured to selectively enclose a plurality of stripper gas containers in an enclosure environment, wherein the enclosure environment is at a ground potential, and wherein each of the plurality of stripper gas containers has a respective stripper gas associated therewith; and
a flow control apparatus configured to selectively fluidly couple each of the stripper gas containers to the charge stripper and to selectively control a flow of each respective stripper gas to the charge stripper.

2. The ion implantation system of claim 1, wherein the flow control apparatus comprises at least one mass flow controller configured to control a respective flow of each respective stripper gas to the charge stripper.

3. The ion implantation system of claim 2, wherein the flow control apparatus further comprises at least one valve selectively fluidly coupled to each of the plurality of stripper gas containers, wherein the at least one valve is configured provide selective fluid communication between the plurality of stripper gas containers and the at least one mass flow controller.

4. The ion implantation system of claim 3, wherein the at least one valve comprises a plurality of valves, wherein each of the plurality of valves is respectively selectively coupled to each of the plurality of stripper gas containers.

5. The ion implantation system of claim 4, wherein the at least one mass flow controller comprises a plurality of mass flow controllers respectively fluidly coupled to the plurality of valves, wherein each of the plurality of mass flow controllers is further configured to control a respective flow of each respective stripper gas to the charge stripper.

6. The ion implantation system of claim 4, further comprising one or more conduits, wherein the charge stripper comprises a stripper tube, and wherein the one or more conduits are fluidly coupled to the stripper tube, wherein the flow control apparatus is further configured to selectively fluidly couple each of the stripper gas containers to the stripper tube via the plurality of valves and the one or more conduits.

7. The ion implantation system of claim 6, further comprising a common conduit fluidly coupling the one or more conduits to the stripper tube, wherein the flow control apparatus is configured to concurrently fluidly couple two or more of the stripper gas containers to the stripper tube via the one or more conduits and the common conduit.

8. The ion implantation system of claim 6, further comprising one or more differential pumps fluidly coupled to the charge stripper, wherein the charge stripper comprises a charge stripper inlet and a charge stripper outlet, wherein the stripper tube is positioned between the charge stripper inlet and the charge stripper outlet, thereby defining two or more gaps between the stripper tube, the charge stripper inlet, and the charge stripper outlet, and wherein the one or more differential pumps are configured to differentially pump the two or more gaps to control a flow of the stripper gas from the charge stripper.

9. The ion implantation system of claim 1, wherein each respective stripper gas is unique for each of the plurality of stripper gas containers.

10. The ion implantation system of claim 1, further comprising a radiation shield, wherein the first linear accelerator and the second linear accelerator are configured to produce x-ray radiation concurrent with the respective acceleration of the ions of the ion beam to the respective first energy and the second energy, and wherein the radiation shield is configured to prevent the x-ray radiation from reaching the enclosure environment.

11. A stripper apparatus for an ion implantation system, the stripper apparatus comprising:
a charge stripper positioned between a first accelerator and a second accelerator along a beam path of an ion beam, wherein the charge stripper is at ground potential;
a gas source enclosure configured to selectively enclose a plurality of stripper gas containers in an enclosure environment, wherein the enclosure environment is at ground potential, and wherein each of the plurality of stripper gas containers has a respective stripper gas associated therewith; and
a flow control apparatus configured to selectively fluidly couple each of the stripper gas containers to the charge stripper and to selectively control a flow of each respective stripper gas to the charge stripper.

12. The stripper apparatus of claim 11, wherein the flow control apparatus comprises at least one mass flow controller configured to control a respective flow of each respective stripper gas to the charge stripper.

13. The stripper apparatus of claim 12, wherein the flow control apparatus further comprises at least one valve selectively fluidly coupled to each of the plurality of stripper gas containers, wherein the at least one valve is configured provide selective fluid communication between the plurality of stripper gas containers and the at least one mass flow controller.

14. The stripper apparatus of claim 12, wherein the flow control apparatus comprises a plurality of valves, wherein each of the plurality of valves is respectively selectively fluidly coupled to each of the plurality of stripper gas containers, and wherein the plurality of valves are configured provide selective fluid communication between the plurality of stripper gas containers and the at least one mass flow controller.

15. The stripper apparatus of claim 14, wherein the at least one mass flow controller comprises a plurality of mass flow controllers respectively fluidly coupled to the plurality of valves, wherein each of the plurality of mass flow controllers is further configured to control a respective flow of each respective stripper gas to the charge stripper.

16. The stripper apparatus of claim 14, further comprising one or more conduits, wherein the charge stripper comprises a stripper tube, and wherein the one or more conduits are fluidly coupled to the stripper tube, wherein the flow control apparatus is further configured to selectively fluidly couple each of the stripper gas containers to the stripper tube via the plurality of valves and the one or more conduits.

17. The stripper apparatus of claim 16, further comprising a common conduit fluidly coupling the one or more conduits to the stripper tube, wherein the flow control apparatus is configured to concurrently fluidly couple two or more of the stripper gas containers to the stripper tube via the one or more conduits and the common conduit.

18. The stripper apparatus of claim 11, wherein each respective stripper gas is associated with a respective species of the ion beam.

19. The stripper apparatus of claim 11, wherein the first accelerator and the second accelerator respectively comprise RF linear accelerators.

20. A charge stripping system for an ion implantation system, the charge stripping system comprising:
a charge stripper positioned between a first RF linear accelerator and a second RF linear accelerator along a beam path of an ion beam, wherein the charge stripper comprises a stripper tube and is at ground potential;
a gas source enclosure configured to selectively enclose a plurality of stripper gas containers in an enclosure environment, wherein the enclosure environment is at ground potential, and wherein each of the plurality of stripper gas containers has a respective stripper gas associated therewith;
a plurality of conduits fluidly coupling the stripper tube to the plurality of stripper gas containers; and
a flow control apparatus configured to selectively control a flow of each respective stripper gas through the plurality of conduits to the stripper tube.
